(19) United States
(12) Patent Application Publication
(10) Pub. No.: US 2023/0318199 A1
(43) Pub. Date: Oct. 5, 2023

(54) ABSORPTION DEVICE FOR ABSORBING ELECTROMAGNETIC RADIATION

(71) Applicant: SH Immobilien GmbH, Bludenz (AT)

(72) Inventor: Ernst SCHWARZHANS, Bludenz (AT)

(73) Assignee: SH Immobilien GmbH, Bludenz (AT)

(21) Appl. No.: 18/022,882

(22) PCT Filed: Aug. 31, 2020
(86) PCT No.: PCT/EP2020/074195

§ 371 Date: Feb. 23, 2023

(51) Int. Cl. H01Q 17/00; H05K 9/00

(52) U.S. Cl. CPC H01Q 17/002; H05K 9/0083

(57) ABSTRACT

An absorption device for absorbing electromagnetic radiation at least in a partial range within a frequency range from 500 MHz to 15 GHz includes a housing (1), which is at least partially transmissive to the electromagnetic radiation to be absorbed and has an inner receptacle space (3), which contains a fill, which includes irregularly arranged absorption elements (4). The absorption elements each include a carrier body (4a) made of an electrically insulating material, on which a layer (4b) is applied externally at least on one side, which is formed by an electrically conductive material.

### CROSS-REFERENCE TO RELATED APPLICATIONS

This application is a 371 National Phase of International Application No. PCT/EP2020/074195, which is incorporated herein by reference as if fully set forth.

### TECHNICAL FIELD

The invention relates to an absorption device for absorbing electromagnetic radiation at least in a partial range within a frequency range from 500 MHz to 15 GHz, wherein preferably electromagnetic radiation is at least to be absorbed in the range from 800 MHz to 6 GHz.

### BACKGROUND

In HF, microwave, and radar technology and in EMC practice, there are various possibilities for absorbing electromagnetic waves.

One solution which functions well provides lining a room with so-called pyramid absorbers. These foams, which are filled with carbon black and/or graphite, in cone or pyramid shape “swallow” electromagnetic waves, which are incident as perpendicularly as possible on the absorbers, very efficiently. However, this shielding efficiency is only achieved if the length of the cones is at least in the order of magnitude of a wavelength of the frequency to be swallowed. This means that the cone length is to be at least 30 cm to 40 cm to absorb GSM 900 frequencies. This dimensioning would be much too voluminous for a practical room lining and therefore does not come into consideration.

Another proven wavelength absorption method is to line the walls of the room using special ferrite tiles. The lossy ferrite material damps the magnetic fields of the stray electromagnetic waves in a broad frequency range. The implementation in the living area fails due to the high weight of the tiles, the fastening problems, and the costs, however.

Especially in radar technology, but also in room linings, multiple absorbing surfaces can be arranged one behind another at quarter-wave distance for a special frequency (Salesbury sheets or Jaumann absorbers). Good elimination of electromagnetic waves is achieved here by destructive interference, presuming the waves are incident perpendicularly on the surface and have the frequency, according to which the quarter-wave distance was dimensioned. One disadvantage here is that the absorption is only effective for vertically incident electromagnetic waves and the effectiveness is not provided in a larger frequency range.

### SUMMARY

The object of the invention is to provide an advantageous absorption device of the type mentioned at the outset, which is active in a partial range within the frequency range from 500 MHz to 15 GHz, wherein this partial range preferably extends at least from 800 MHz to 6 GHz, specifically for electromagnetic waves of different directions of incidence.

This is achieved according to the invention by an absorption device having one or more of the features disclosed herein.

The absorption device of the invention includes a housing, which is cuboid, for example, and which is at least partially transmissive for the electromagnetic radiation to be absorbed and has an inner receptacle space. A fill is contained therein, which includes irregularly arranged absorption elements. These absorption elements each include a carrier body made of an electrically insulating material, on which a layer is applied externally at least on one side, which consists of an electrically conductive material.

Lossy electric currents can be induced in the electrically conductive layers of the absorption elements by electromagnetic radiation incident on the absorption device. Scattering of incident electromagnetic radiation occurs due to the different orientations of the absorption elements. An advantageous absorption of the electromagnetic radiation can be achieved by these effects.

The longitudinal extensions of the electrically conductive layers of the absorption elements are advantageously in the range from 2 cm to 25 cm, preferably in the range from 3 cm to 15 cm, wherein preferably absorption elements having different longitudinal extensions of the electrically conductive layers are provided. Resonances can thus be formed for different wavelengths in the desired absorption range in order to achieve effective absorption.

The absorption elements have cuboid shapes in one advantageous embodiment of the invention, wherein the lengths of these cuboids are preferably more than twice, particularly preferably more than three times greater than the widths and thicknesses.

For example, the insulating carrier bodies of the absorption elements can consist of corrugated cardboard. The electrically conductive layer of the carrier bodies is preferably formed by a coating. In particular, the carrier bodies are only coated on one side in this case.

The fill advantageously fills up the receptacle space of the housing as extensively as possible, wherein it is preferred for the fill to fill up the receptacle space over at least 90% of its height.

At least one of the two opposing large surfaces of the housing is expediently at least 50% transmissive to the radiation to be absorbed. As mentioned, the range of the radiation to be absorbed is in a partial range within the frequency range from 500 MHz to 15 GHz. For example, the range of the radiation to be absorbed can extend from at least 800 MHz to 6 GHz.

The other of the opposing large surfaces of the housing can include an electrically conductive layer. A reflection of the electromagnetic radiation incident on this side can thus be achieved, so that it is reflected back again into the area of the fill having the absorption elements. The absorption of the absorption device can thus be increased further.

To prevent long-term stronger collapse of the fill, the receptacle space of the housing can be divided into multiple partial spaces vertically by intermediate walls.

In advantageous embodiments of the invention, the absorption device can form a wall, ceiling, or floor element. The housing of the absorption device can advantageously be formed cuboid-shaped in this case. For example, a bed having an end-face wall arranged at the head end and/or foot end can be provided, which is formed by an absorption device according to the invention. Additionally or alternatively, the bed can be provided with a cover, which is formed by an absorption device according to the invention.

In particular electromagnetic waves, as are used in the GSM network, are preferably absorbed by an absorption device according to the invention.

The radiation exposure of persons located in a space can be reduced by a device according to the invention.

### BRIEF DESCRIPTION OF THE DRAWINGS

Further advantages and details of the invention are explained hereinafter on the basis of the appended schematic drawing.

In the figures:

FIG. 1 shows a diagonal view of an exemplary embodiment of an absorption device according to the invention;

FIG. 2 shows a schematic horizontal partial section along line A-A from FIG. 1;

FIG. 3 shows a schematic vertical partial section along line B-B from FIG. 1;

FIG. 4 shows a diagonal view of an absorption element;

FIG. 5 shows a schematic section through the absorption element along line C-C from FIG. 4; and

FIG. 6 shows a further possible embodiment of an absorption element in a section similar to FIG. 5.

### DETAILED DESCRIPTION

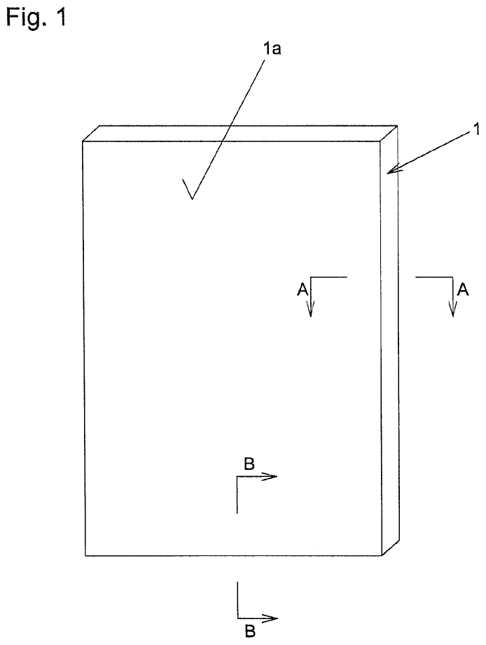

An exemplary embodiment of an absorption device according to the invention is shown very schematically in FIGS. 1 to 5. The absorption device includes a housing 1, which is formed cuboid-shaped in the exemplary embodiment. Other housing shapes are conceivable and possible, wherein it is preferred that the housing includes parallel opposing large surfaces 1a, 1b, the dimensions of which are substantially larger than the thickness s of the housing measured at right angles thereto, preferably more than five times as large.

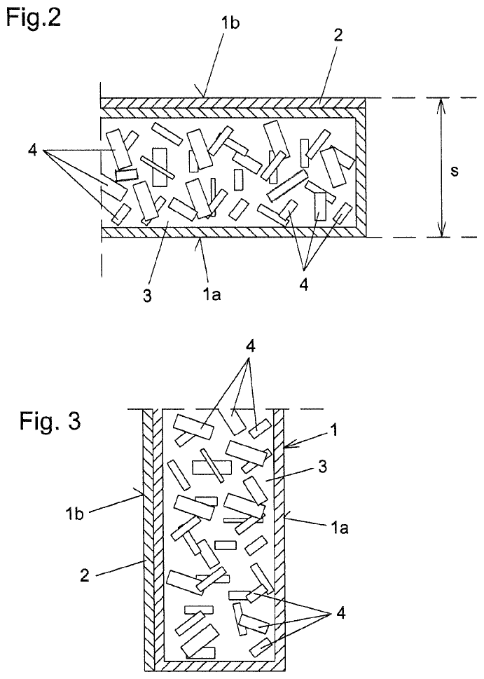

One of the large surfaces 1b includes a layer 2 made of an electrically conductive material in the exemplary embodiment. The layer 2 can be formed, for example, by an electrically conductive film adhesively bonded on an electrically insulating material, for example wood. The thickness of the layer 2 is shown exaggerated in FIGS. 2 and 3.

The wall of the housing 1 forming the opposing large surface 1a is at least 50% transmissive for the electromagnetic radiation to be absorbed. This large surface 1a is preferably 50% transmissive at least for radiation from 800 MHz to 5 GHz, preferably for radiation from 500 MHz to 15 GHz. For example, this wall 1a can be formed at least partially by a fabric cover. Wooden or plastic plates which are possibly used are advantageously provided with the largest possible holes. Dielectric supports can be provided behind this, in order to prevent yielding or breaking through of the wall.

The housing 1 includes a receptacle space 3 in the interior. A fill is arranged therein, which includes absorption elements 4, as is shown only very schematically in FIGS. 2 and 3. For example, the fill can be formed completely by absorption elements 4. In addition, the fill could also contain filler elements.

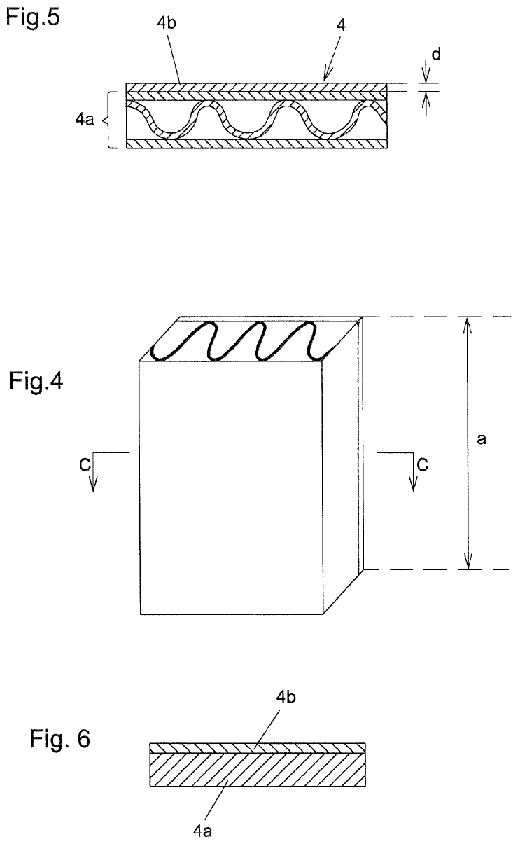

As is apparent from FIGS. 4 and 5, a respective absorption element 4 includes a carrier body 4a made of an electrically insulating material, on which a layer 4b of electrically conductive material is applied externally at least on one side, which is preferably one of the large surfaces of the carrier body 4a. At least one side of the carrier body 4a advantageously does not have a layer made of electrically conductive material, is thus made insulating. A respective absorption element 4 preferably only has a layer 4b made of electrically conductive material on one side.

If filler elements are provided in addition to the absorption elements, they are preferably formed completely by electrically insulating material. Such filler elements could be provided, for example, to avoid long-term settling of the filling. To avoid stronger long-term settling of the filling, the housing can alternatively or additionally include horizontal intermediate walls, which divide the receptacle space 3 vertically into multiple partial spaces.

The fill fills up the receptacle space 3 as completely as possible, wherein it preferably extends over at least 90% of the height of the receptacle space 3.

The specific resistance of the carrier body 4a of a respective absorption element 4 is preferably at least 106 Ω·mm²/m, preferably more than 10⁹ Ω·mm²/m.

The specific resistance of the electrically conductive layer 4b applied on at least one side is preferably less than 1000 Ω·mm²/m. A value of greater than 0.1 Ω·mm²/m is advantageous to cause a corresponding loss of the excited currents. The specific resistance of the at least one electrically conductive layer 4b of a respective absorption element 4 is preferably in the range from 1-100 Ω·mm²/m.

One possible embodiment of the absorption elements 4 is shown in more detail in FIGS. 5 and 6. The carrier bodies are formed at least essentially cuboid-shaped, wherein their lengths are preferably substantially greater, preferably at least three times greater, than their widths and thicknesses.

In this exemplary embodiment, the carrier body 4a is formed by corrugated cardboard. One of the large surfaces of the carrier body 4a is coated using the electrically conductive material to form the electrically conductive layer 4b. The coating can be carried out by spraying, for example. The electrically conductive layer 4b can contain for this purpose, for example, graphite and binders. The thickness d of the electrically conductive layer 4b is less than 1 mm, preferably less than 0.3 mm.

The conductive layer 4b of a respective absorption element 4 advantageously has a longitudinal extension which corresponds to the entire longitudinal extension of the absorption element 4. To achieve an advantageous absorption in a broader frequency range, absorption elements having different lengths a are advantageously provided, so that the electrically conductive layers 4b also have longitudinal extensions having different lengths a. The longest of the absorption elements 4 is advantageously at least twice as long as the shortest.

Dipoles of different lengths a are thus formed, which can be resonantly excited by frequencies, the wavelength of which corresponds to approximately twice the length, wherein then elevated currents flow in the dipole. Due to the existing electrical resistance of the layer 4b, corresponding losses occur with a certain (very minor) heat development, by which radiant energy can be absorbed.

The lengths a of the absorption elements 4 are in the range from 2 cm to 25 cm, preferably in the range from 3 cm to 15 cm.

Another possible design of an absorption element is shown in FIG. 6. The carrier body is formed in one piece and full volume here, for example the carrier body consists of wood.

Other designs of carrier bodies, which are provided on at least one side, preferably only one side with an electrically conductive layer, are conceivable and possible. For example, a carrier body could also be formed by a textile material, by cork, or by a plastic.

### KEY TO THE REFERENCE NUMERALS

1 housing
1a large surface
1b large surface
2 layer
3 receptacle space
4 absorption element
4a carrier body
4b layer

1. An absorption device for absorbing electromagnetic radiation at least in a partial range within a frequency range from 500 MHz to 15 GHz, the absorption device comprising:
a housing which is at least partially transmissive to the electromagnetic radiation to be absorbed and has an inner receptacle space that contains a fill, which includes irregularly arranged absorption elements; and
the absorption elements each include a carrier body made of an electrically insulating material, on which a layer is applied externally at least on one side that is formed by an electrically conductive material.

2. The absorption device as claimed in claim 1, wherein longitudinal extensions of the electrically conductive layers of the absorption elements are in a range from 2 cm to 25 cm.

3. The absorption device as claimed in claim 1, wherein a thickness of the electrically conductive layer of a respective one of the absorption elements is less than 1.

4. The absorption device as claimed in claim 1, wherein the electrically conductive layer of a respective one of the absorption elements is formed by an electrically conductive coating of the carrier body.

5. The absorption device as claimed in claim 1, wherein at least one lateral surface of the absorption elements is electrically insulating.

6. The absorption device as claimed in claim 1, wherein the fill includes absorption elements having different lengths of the electrically conductive layer.

7. The absorption device as claimed in claim 1, wherein the fill includes absorption elements having different lengths.

8. The absorption device as claimed in claim 1, wherein a specific resistance of the electrically conductive layer of a respective one of the absorption elements is in a range from 0.1 to 1000 Ω·mm²/m.

9. The absorption device as claimed in claim 1, wherein the absorption elements have a cuboid shape.

10. The absorption device as claimed in claim 1, wherein the absorption device is a wall, ceiling, or floor element.
